(19) United States
(12) Patent Application Publication
(10) Pub. No.: US 2026/0213766 A1
(43) Pub. Date: Jul. 23, 2026

(54) INCREMENTAL DELTA-SIGMA MODULATOR

(71) Applicant: Asahi Kasei Microdevices Corporation, Tokyo (JP)

(72) Inventors: Kazuma OHARA, Tokyo (JP); Yuichi MIYAHARA, Tokyo (JP)

(73) Assignee: Asahi Kasei Microdevices Corporation, Tokyo (JP)

(21) Appl. No.: 19/034,870

(22) Filed: Jan. 23, 2025

(51) Int. Cl. H03M 3/00

(52) U.S. Cl. CPC H03M 3/50

(57) ABSTRACT

An incremental delta-sigma modulator comprises: an analog integration unit including multiple integrators connected in series and configured to integrate an analog signal; a quantizer configured to quantize a signal output from the analog integration unit; a DA (Digital-to-Analog) converter configured to convert a digital signal output from the quantizer into a feedback analog signal and output the feedback analog signal to the analog integration unit; a digital integration unit including multiple integrators connected in series and configured to integrate the digital signal from the quantizer; and a controller configured to reset each of the multiple integrators included in the analog integration unit and the multiple integrators included in the digital integration unit for each series of integration operations. At least one of the multiple integrators included in the digital integration unit has a feedback coefficient greater than 0 and less than 1.

### TECHNICAL FIELD

The present disclosure relates to an incremental delta-sigma modulator.

### BACKGROUND

Conventionally, incremental delta-sigma modulators are known as a technology for achieving high speed and high resolution. For example, J. Markus, J. Silva, and G. C. Temes, “Theory and applications of incremental ΔΣ converters,” IEEE Transactions on Circuits and Systems I: Regular Papers, vol. 51, no. 4, pp. 678-690, April 2004, doi: 10.1109/TCSI.2004.826202, disclose that increasing the order of incremental delta-sigma modulators improves resolution.

### SUMMARY

However, conventional incremental delta-sigma modulators have a problem that increasing their order to improve resolution instead causes significant degradation in their filtering effect. It is, therefore, an object of the present disclosure to provide an incremental delta-sigma modulator with improved resolution and filtering effect.

In order to achieve the object, one aspect of the present disclosure is an incremental delta-sigma modulator comprising:
an analog integration unit including multiple integrators connected in series and configured to integrate an analog signal, each of the multiple integrators having a first-order or higher-order feedback coefficient;
a quantizer configured to quantize a signal output from the analog integration unit;
a DA (Digital-to-Analog) converter configured to convert a digital signal output from the quantizer into a feedback analog signal and output the feedback analog signal to the analog integration unit;
a digital integration unit including multiple integrators connected in series and configured to integrate the digital signal from the quantizer, each of the multiple integrators having a first-order or higher-order feedback coefficient; and
a controller configured to reset each of the multiple integrators included in the analog integration unit and the multiple integrators included in the digital integration unit for each series of integration operations.

Moreover, at least one of the multiple integrators included in the digital integration unit has a feedback coefficient greater than 0 and less than 1.

The above-mentioned incremental delta-sigma modulator can achieve both high resolution and high filtering effect. Therefore, the present disclosure can provide an incremental delta-sigma modulator with improved utility.

As used herein, the term “multiple integrators connected in series” generally refers to multiple integrators connected such that the output of one of the integrators serves as the input to another one of the integrators.

As used herein, the term “feedback coefficient” of an integrator generally refers to a gain of a feedback circuit arranged in a feedback path of the integrator. For example, if a feedback circuit that amplifies an input signal by a gain of x is arranged in a feedback path of an integrator, the integrator has the feedback coefficient of x. For example, if a feedback circuit that amplifies an input signal by a gain of 1 is arranged in the feedback path of the integrator, or if no feedback circuit is arranged in the feedback path of the integrator, the integrator has the feedback coefficient of 1.

As used herein, the term “a series of integration operations” generally refers to a set of integration operations that is repeatedly performed in an incremental delta-sigma modulator. The number of integration operations included in a series of integration operations may be determined based on the design of the incremental delta-sigma modulator. In the processing of the incremental delta-sigma modulator, a reset period may be provided for performing a reset process to reset internal circuits such as integrators for each series of integration operations. In that case, a series of integration operations may refer to multiple integration operations executed between two reset periods. A series of integration operations may be executed according to the clock cycle used in the incremental delta-sigma modulator. A series of integration operations may also be designed according to the sampling period and/or output rate of the incremental delta-sigma modulator.

In the preceding incremental delta-sigma modulator, the feedback coefficient of the at least one of the multiple integrators included in the digital integration unit is configured to be variable.

In the preceding incremental delta-sigma modulators, the at least one of the multiple integrators included in the digital integration unit preferably comprises a logic circuit configured to vary the feedback coefficient.

In the preceding incremental delta-sigma modulators, the multiple integrators included in the digital integration unit preferably include two or more integrators, each having the feedback coefficient greater than 0 and less than 1. Moreover, values of the feedback coefficients of the two or more integrators are preferably different from each other.

In the preceding incremental delta-sigma modulators, the at least one of the multiple integrators included in the digital integration unit preferably comprises: a first feedback module having the feedback coefficient greater than 0 and less than 1; and a second feedback module having a feedback coefficient of 1. Moreover, the first feedback module and the second feedback module are preferably configured to be switchable.

In the preceding incremental delta-sigma modulators, at least one of the multiple integrators included in the analog integration unit preferably has the feedback coefficient greater than 0 and less than 1.

In the preceding incremental delta-sigma modulators, the feedback coefficient of the at least one of the multiple integrators included in the analog integration unit is preferably configured to be variable.

In the preceding incremental delta-sigma modulators, the at least one of the multiple integrators included in the analog integration unit preferably comprises a variable capacitor. Moreover, the feedback coefficient of the at least one of the multiple integrators included in the analog integration unit is preferably configured to be varied according to each integration operation included in the series of integration operations.

In the preceding incremental delta-sigma modulators, the multiple integrators included in the analog integration unit preferably include two or more integrators, each having the feedback coefficient greater than 0 and less than 1. Moreover, values of the feedback coefficients of the two or more integrators are different from each other.

In the preceding incremental delta-sigma modulators, the at least one of the multiple integrators included in the analog integration unit preferably comprises: a first feedback module having the feedback coefficient greater than 0 and less than 1; and a second feedback module having a feedback coefficient of 1. Moreover, the first feedback module and the second feedback module are preferably configured to be switchable.

In the preceding incremental delta-sigma modulators, a number of the multiple integrators included in the digital integration unit is preferably greater than a number of the multiple integrators included in the analog integration unit.

The preceding incremental delta-sigma modulator preferably further comprises:
an input terminal configured to receive an analog signal; and
an adder-subtractor configured to subtract the feedback analog signal from the DA converter from the analog signal received at the input terminal to generate a subtracted analog signal and output the subtracted analog signal to the analog integration unit.

The preceding incremental delta-sigma modulator preferably further comprises an adder coupled between the analog integration unit and the quantizer. Moreover, the adder is preferably configured to: add signals output from the multiple integrators included in the analog integration unit and the analog signal received by the input terminal to generate an added signal and; output the added signal to the quantizer.

Accordingly, the present disclosure can provide an incremental delta-sigma modulator with improved resolution and filtering effect.

### BRIEF DESCRIPTION OF THE DRAWINGS

Various other objects, features, and attendant advantages of the present invention will become fully appreciated as the same becomes better understood when considered in conjunction with the accompanying drawings, in which like reference characters designate the same or similar parts throughout the several views, and wherein:

FIG. 1 illustrates a schematic configuration of an incremental delta-sigma modulator according to an embodiment of the present disclosure;

FIG. 2 illustrates a configuration of the integrator in the incremental delta-sigma modulator shown in FIG. 1;

FIG. 3 illustrates a circuit configuration of an analog integrator having a feedback coefficient greater than 0 and less than 1;

FIG. 4 illustrates a schematic configuration of the incremental delta-sigma modulator in Example 1;

FIG. 5 is a graph illustrating the filter coefficients of the incremental delta-sigma modulators in Example 1 and Comparative Example 1;

FIG. 6 illustrates a schematic configuration of the incremental delta-sigma modulator in Comparative Example 1;

FIG. 7 is a graph illustrating the transfer functions of the incremental delta-sigma modulators in Example 1 and Comparative Examples 1 and 2;

FIG. 8 illustrates a schematic configuration of the incremental delta-sigma modulator in Comparative Example 2;

FIG. 9 illustrates a schematic configuration of the first modification of the incremental delta-sigma modulator shown in FIG. 1;

FIG. 10 illustrates a schematic configuration of the second modification of the incremental delta-sigma modulator shown in FIG. 1;

FIG. 11 illustrates a configuration of the integrator in the second modification shown in FIG. 10;

FIG. 12 illustrates a schematic configuration of the incremental delta-sigma modulator in Example 2;

FIG. 13 is a graph illustrating the filter coefficients of the incremental delta-sigma modulators in Example 2; and

FIG. 14 is a graph illustrating the transfer functions of the incremental delta-sigma modulators in Example 2 and Comparative Example 1.

### DETAILED DESCRIPTION

An incremental delta-sigma modulator 1 according to an embodiment of the present disclosure will be described below with reference to the accompanying drawings. In the following description of the present embodiment, the description of the same or corresponding parts will be omitted or simplified as appropriate. In each drawing, the same reference characters designate the same or corresponding parts.

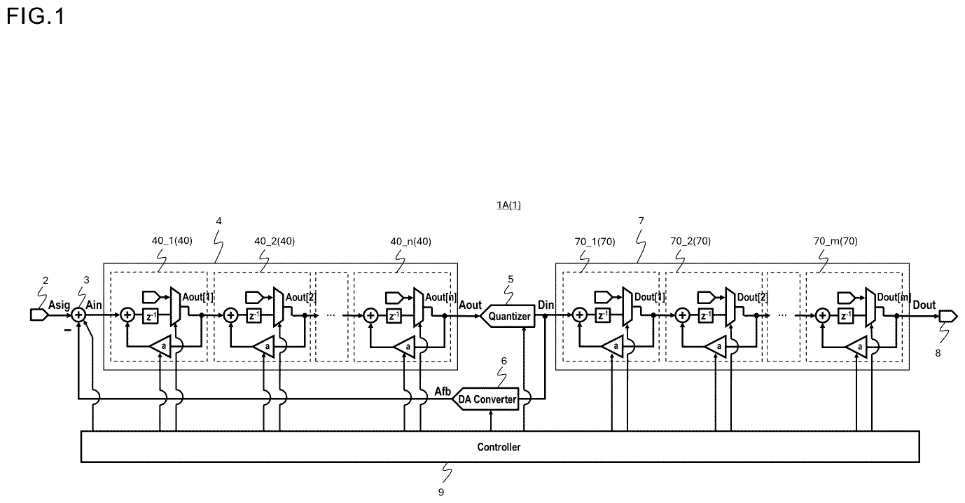

At first, with reference to FIG. 1, a configuration of an incremental delta-sigma modulator 1 according to an embodiment of the present embodiment will be described. FIG. 1 illustrates a schematic configuration of the incremental delta-sigma modulator 1. In FIG. 1, the incremental delta-sigma modulator 1 is indicated as incremental delta-sigma modulator 1A to distinguish it from variations of the incremental delta-sigma modulator 1 that will be described below. However, in the following description, when there is no specific distinction between incremental delta-sigma modulator 1A and other variations of incremental delta-sigma modulator 1, they are collectively referred to as “incremental delta-sigma modulator 1”.

The incremental delta-sigma modulator 1 (1A) comprises an input terminal 2, an adder-subtractor 3, an analog integration unit 4, a quantizer 5, a DA converter 6 (Digital-to-Analog converter 6), a digital integration unit 7, an output terminal 8, and a controller 9. The incremental delta-sigma modulator 1 is an incremental-type AD converter (Analog-to-Digital converter) that converts the analog signal Asig input to the input terminal 2 into a digital signal Dout with resetting internal circuits and outputs the digital signal Dout from the output terminal 8.

The input terminal 2 receives an analog signal Asig. In the present embodiment, the input terminal 2 is connected to the adder-subtractor 3. The input terminal 2 is configured to be connectable to an external device located outside the incremental delta-sigma modulator 1. The input terminal 2 receives the analog signal Asig input from the external device. The input terminal 2 outputs the received analog signal Asig to the adder-subtractor 3.

The adder-subtractor 3 subtracts the feedback analog signal Afb from the DA converter 6 from the analog signal Asig received at the input terminal 2 to generate a subtracted analog signal Ain and outputs the subtracted analog signal Ain to the analog integration unit 4. In the present embodiment, the adder-subtractor 3 is connected to the input terminal 2, the analog integration unit 4, and the DA converter 6. The adder-subtractor 3 receives the analog signal Asig from the input terminal 2 and the feedback analog signal Afb from the DA converter 6. The adder-subtractor 3 subtracts the feedback analog signal Afb from the analog signal Asig to generate the analog signal Ain. The adder-subtractor 3 may perform this subtraction in accordance with the clock signal supplied by the controller 9. The adder-subtractor 3 outputs the generated analog signal Ain to the analog integration unit 4.

The analog integration unit 4 integrates the analog signal Ain. In the present embodiment, the analog integration unit 4 is connected to the adder-subtractor 3 and the quantizer 5. The analog integration unit 4 receives the analog signal Ain from the adder-subtractor 3. The analog integration unit 4 integrates the analog signal Ain to generate an analog signal Aout. The analog integration unit 4 may integrate the analog signal Ain in accordance with a clock signal supplied by the controller 9. The analog integration unit 4 outputs the generated analog signal Aout to the quantizer 5.

The analog integration unit 4 includes multiple integrators 40_1 to 40_n connected in series. Here, n is a natural number equal to or greater than 2. Hereinafter, the integrators 40_1 to 40_n are collectively referred to simply as “integrator 40” when they are not distinguished from one another. Each of the plurality of integrators 40 is an analog integrator having a first-order or higher-order feedback coefficient.

Connecting multiple integrators 40 in series means connecting the multiple integrators 40 so that the output of one of the integrators 40 serves as the input of another one of the integrators 40. In FIG. 1, the first integrator 40_1 integrates the analog signal Ain from the adder-subtractor 3 and outputs the integrated analog signal Aout[1] to the second integrator 40_2. The second integrator 40_2 integrates the analog signal Aout[1] from the first integrator 40_1 and outputs the integrated analog signal Aout[2] to the third integrator 40_3. The n-th integrator 40_n integrates the analog signal Aout[_n−1] from the (n−1)-th integrator 40_n−1 and outputs the integrated analog signal Aout[n] to the quantizer 5 as the analog signal Aout.

The quantizer 5 quantizes the signal Aout output from the analog integration unit 4. In the present embodiment, the quantizer 5 is connected to the analog integration unit 4, the DA converter 6, and the digital integration unit 7. The quantizer 5 receives the analog signal Aout from the analog integration unit 4. The quantizer 5 quantizes the analog signal Aout to generate a digital signal Din. The quantizer 5 may quantize the analog signal Aout in accordance with a clock signal supplied by the controller 9. The quantizer 5 outputs the generated digital signal Din to the DA converter 6 and the digital integration unit 7. The quantizer 5 may be a 1-bit quantizer configured to output a binary digital signal. Alternatively, the quantizer 5 may be a multi-bit quantizer configured to output a multi-level digital signal.

The DA converter 6 converts the digital signal Din from the quantizer 5 into a feedback analog signal Afb. In the present embodiment, the DA converter 6 is connected to the adder-subtractor 3 and the quantizer 5. The DA converter 6 receives the digital signal Din from the quantizer 5. The DA converter 6 performs DA conversion (Digital-to-Analog conversion) of the received digital signal Din to generate the feedback analog signal Afb. The DA converter 6 may perform the DA conversion in accordance with a clock signal supplied by the controller 9. The DA converter 6 outputs the generated feedback analog signal Afb to the adder-subtractor 3. The feedback analog signal Afb from the DA converter 6 is input to the analog integration unit 4 via the adder-subtractor 3. That is, the DA converter 6 converts the digital signal Din output from the quantizer 5 into a feedback analog signal Afb and outputs the feedback analog signal Afb to the analog integration unit 4.

The digital integration unit 7 integrates the digital signal Din from the quantizer 5. In the present embodiment, the digital integration unit 7 is connected to the quantizer 5 and the output terminal 8. The digital integration unit 7 receives the digital signal Din from the quantizer 5. The digital integration unit 7 integrates the received digital signal Din to generate a digital signal Dout. The digital integration unit 7 may integrate the digital signal Din in accordance with a clock signal supplied by the controller 9. The digital integration unit 7 outputs the generated digital signal Dout to the output terminal 8.

The digital integration unit 7 includes multiple integrators 70_1 to 70_m connected in series. Here, m is a natural number equal to or greater than 2. Hereinafter, the integrators 70_1 to 70_m are collectively referred to simply as “integrator 70” when they are not distinguished from one another. Each of the plurality of integrators 70 is a digital integrator having a first-order or higher-order feedback coefficient.

In FIG. 1, the first integrator 70_1 integrates the digital signal Din from the quantizer 5 and outputs the integrated digital signal Dout[1] to the second integrator 70_2. The second integrator 70_1 integrates the digital signal Dout[1] from the first integrator 70_1 and outputs the integrated digital signal Dout[2] to the third integrator 70_3. The m-th integrator 70_m integrates the digital signal Dout[m−1] from the (m−1)-th integrator 70_m−1 and outputs the integrated digital signal Dout[m] to the output terminal 8 as the digital signal Dout.

The number m of the multiple integrators 70 included in the digital integration unit 7 may be the same as the number n of the multiple integrators 40 included in the analog integration unit 4. Alternatively, the number m of the multiple integrators 70 included in the digital integration unit 7 may be greater than the number n of the multiple integrators 40 included in the analog integration unit 4. For example, the number m may be equal to the number n+1.

The output terminal 8 outputs a digital signal Dout. In the present embodiment, the output terminal 8 is connected to the digital integration unit 7. The output terminal 8 is configured to be connectable to an external device located outside the incremental delta-sigma modulator 1. The output terminal 8 receives the digital signal Dout from the digital integration unit 7. The output terminal 8 outputs the received digital signal Dout to the external device.

The controller 9 includes one or more control circuits. The controller 9 is communicatively connected to each component included in the incremental delta-sigma modulator 1, such as the input terminal 2, the adder-subtractor 3, the analog integration unit 4, the quantizer 5, the DA converter 6, the digital integration unit 7, and the output terminal 8. Accordingly, the controller 9 controls the operations of the incremental delta-sigma modulator 1.

For example, the controller 9 transmits a clock signal to the adder-subtractor 3, the analog integration unit 4, the quantizer 5, the DA converter 6, and the digital integration unit 7 to control the timing of their operations. As a result, the controller 9 causes the adder-subtractor 3, the analog integration unit 4, the quantizer 5, the DA converter 6, and the digital integration unit 7 to execute processing in clock cycles. The clock signal may be supplied to the controller 9 from an external device located outside the incremental delta-sigma modulator 1. Alternatively, the controller 9 may comprise a clock oscillator to generate a clock signal.

Further, for example, the controller 9 transmits a reset signal for resetting the integrated value to each of the multiple integrators 40 included in the analog integration unit 4 and the multiple integrators 70 included in the digital integration unit 7. Upon receiving the reset signal from the controller 9, each of the multiple integrators 40 included in the analog integration unit 4 and the multiple integrators 70 included in the digital integration unit 7 performs a reset operation to reset the integrated value held by each of them. The controller 9 may transmit the reset signal to each of the multiple integrators 40 included in the analog integration unit 4 and the multiple integrators 70 included in the digital integration unit 7 either before starting a series of integration operations or after completing a series of integration operations. The controller 9 resets each of the multiple integrators 40 included in the analog integration unit 4 and the multiple integrators 70 included in the digital integration unit 7 for each series of integration operations.

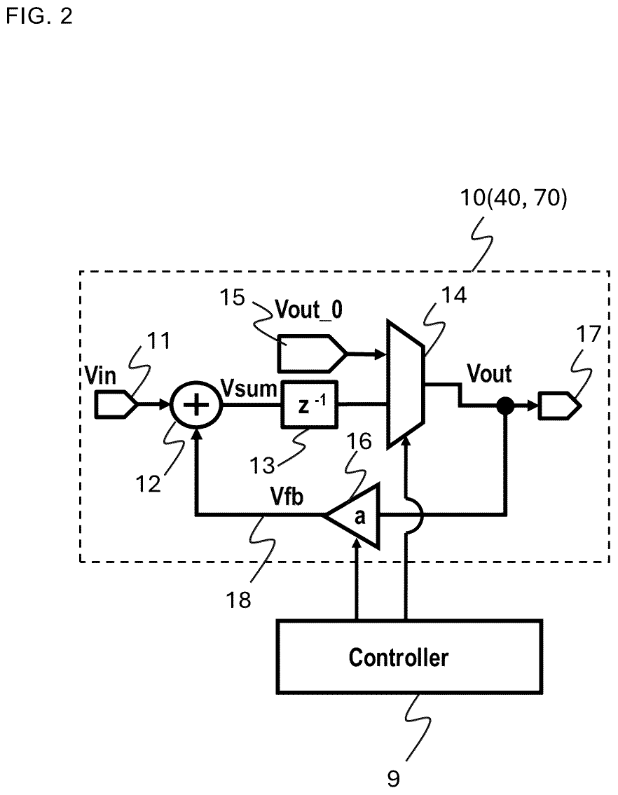

Next, with reference to FIG. 2, configurations of the integrator 40 included in the analog integration unit 4 and the integrator 70 included in the digital integration unit 7 in the incremental delta-sigma modulator 1 will be described. FIG. 2 illustrates a configuration of the integrator 10 (40, 70) in the incremental delta-sigma modulator 1 shown in FIG. 1. In the present disclosure, the integrator 40 and the integrator 70 are collectively referred to simply as “integrator 10” when they are not distinguished from each other.

As shown in FIG. 2, the integrator 10 receives a signal Vin. The integrator 10 integrates the received signal Vin to generate a signal Vout. Then, the integrator 10 outputs the integrated signal Vout. If the integrator 10 is an analog integrator (integrator 40), the signals Vin and Vout are analog signals. If the integrator 10 is a digital integrator (integrator 70), the signals Vin and Vout are digital signals.

The integrator 10 includes an input terminal 11, an adder 12, a delay circuit 13, a switch circuit 14, a reset circuit 15, a feedback circuit 16, and an output terminal 17. The integrator 10 has a feedback path 18 configured to feed back the output Vout from the switch circuit 14 to the adder 12.

The input terminal 11 is connected to the adder 12. The input terminal 11 receives the signal Vin. The input terminal 11 outputs the received signal Vin to the adder 12.

The adder 12 is connected to the input terminal 11, the delay circuit 13, and the feedback circuit 16. The adder 12 receives the signal Vin input to the input terminal 11 and the feedback signal Vfb from the feedback circuit 16. The adder 12 adds the signal Vin and the feedback signal Vfb to generate the signal Vsum. The adder 12 outputs the generated signal Vsum to the delay circuit 13.

The delay circuit 13 is connected to the adder 12 and the switch circuit 14. The delay circuit 13 receives the signal Vsum from the adder 12. The delay circuit 13 delays the received signal Vsum and outputs it to the switch circuit 14. The delay circuit 13 has the transfer function Z⁻¹.

The switch circuit 14 is connected to the delay circuit 13, the reset circuit 15, the feedback circuit 16, and an output terminal 17. The switch circuit 14 is communicatively connected to the controller 9. The switch circuit 14 receives the signal from the delay circuit 13 and the signal from the reset circuit 15. The switch circuit 14 outputs one of the signal from the delay circuit 13 and the signal from the reset circuit 15, as a signal Vout, to the feedback circuit 16 and the output terminal 17. The switch circuit 14 switches the output in accordance with a reset signal supplied by the controller 9. Upon receiving a reset signal, the switch circuit 14 outputs the signal from the reset circuit 15 as the signal Vout. Upon not receiving a reset signal, the switch circuit 14 outputs the signal from the delay circuit 13 as the signal Vout.

The reset circuit 15 is connected to the switch circuit 14. The reset circuit 15 outputs an initial signal Vout_0 to the switch circuit 14. The initial signal Vout_0 is an initial value of the output of the integrator 10, and is set to, for example, a common voltage (0 V).

The feedback circuit 16 is connected to the adder 12 and the switch circuit 14. The feedback circuit 16 is communicatively connected to the controller 9. The feedback circuit 16 is placed on the feedback path 18. The feedback circuit 16 amplifies the signal Vout from the switch circuit 14 by a gain of a and outputs the amplified signal to the adder 12. Specifically, the feedback circuit 16 receives the signal Vout from the switch circuit 14. The feedback circuit 16 amplifies the received signal Vout by a gain of a to generate a feedback signal Vfb. The feedback circuit 16 outputs the generated feedback signal Vfb to the adder 12. In this manner, the integrator 10 operates as an integrator having a feedback coefficient of a. In case the feedback coefficient a is greater than 0 and less than 1, the feedback circuit 16 may attenuate the signal Vout. In this case, the feedback circuit 16 may function as an attenuator.

With reference again to FIG. 1, at least one of the multiple integrators 40 included in the analog integration unit 4 may comprise the feedback circuit 16 having the gain a set to a value greater than 0 and less than 1. That is, at least one of the multiple integrators 40 included in the analog integration unit 4 may have a feedback coefficient a greater than 0 and less than 1. In the embodiment shown in FIG. 1, all of the multiple integrators 40_1 to 40_n have feedback coefficients a greater than 0 and less than 1. However, as will be described later as Embodiment 1, the multiple integrators 40 included in the analog integration unit 4 may include an integrator having a feedback coefficient of 1.

When the multiple integrators 40 included in the analog integration unit 4 include two or more integrators 40 each having a feedback coefficient a greater than 0 and less than 1, the values of the feedback coefficients a of the two or more integrators 40 may be different from each other. This allows more detailed design of the resolution and filtering effect in the incremental delta-sigma modulator 1. However, the multiple integrators 40_1 to 40_n shown in FIG. 1 may have feedback coefficients a equal to each other. This reduces the processing load on the controller 9 for controlling the multiple integrators 40 in the incremental delta-sigma modulator 1.

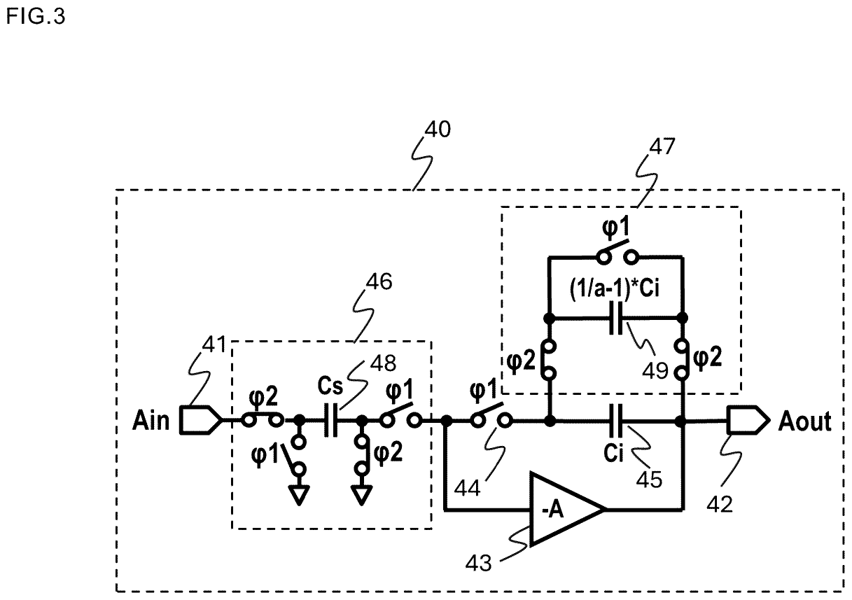

With reference to FIG. 3, an example of a circuit configuration of the integrator 40 will be described. FIG. 3 illustrates a circuit configuration of an analog integrator 40 having a feedback coefficient greater than 0 and less than 1.

The integrator 40 includes an input terminal 41, an output terminal 42, an amplifier 43, a switch circuit 44, a feedback capacitor 45, a first switched capacitor circuit 46, and a second switched capacitor circuit 47. The input terminal 41, the output terminal 42, the amplifier 43, the switch circuit 44, the feedback capacitor 45, the first switched capacitor circuit 46, and the second switched capacitor circuit 47 of the integrator 40 may be controlled by the controller 9. In this way, the controller 9 controls the operation of the integrator 40.

The amplifier 43 and the first switched capacitor circuit 46 are connected in series between the input terminal 41 and the output terminal 42. The input terminal of the first switched capacitor circuit 46 is connected to the input terminal 41 of the integrator 40. The input terminal of the amplifier 43 is connected to the output terminal of the first switched capacitor circuit 46. The output terminal of the amplifier 43 is connected to the output terminal 42 of the integrator 40.

The switch circuit 44 and the feedback capacitor 45 are connected in parallel with the amplifier 43 between the first switched capacitor circuit 46 and the output terminal 42. The switch circuit 44 is connected to the input terminal of the amplifier 43 and the input terminal of the feedback capacitor 45. The output terminal of the feedback capacitor 45 is connected to the output terminal 42 and the output terminal of the amplifier 43.

The switch circuit 44 has one or more switches. The switch circuit 44 controls charging, discharging, and holding of the feedback capacitor 45. The feedback capacitor 45 stores an input signal when the switch circuit 44 is enabled. The first switched capacitor circuit 46 is provided between the input terminal 41 and the input terminal of the amplifier 43. The first switched capacitor circuit 46 repeats the process of charging with the analog signal Vin input to the integrator 40 and discharging it to the amplifier 43.

The first switched capacitor circuit 46 comprises a first capacitor 48 and one or more switches. The first capacitor 48 has a capacitance of Cs. The first switched capacitor circuit 46 repeats the charging and discharging of the first capacitor 48 corresponding to two phases, φ1 and φ2 (for example, high/low), which repeat within each clock cycle. For example, during the period φ1, the first switched capacitor circuit 46 may connect the input terminal of the first capacitor 48 to the reference potential and connect the output terminal of the first capacitor 48 to the input terminal of the amplifier 43, causing the first capacitor 48 to discharge. During the period φ2, the first switched capacitor circuit 46 may connect the input terminal of the first capacitor 48 to the input terminal 41 of the integrator 40 and connect the output terminal of the first capacitor 48 to a reference potential, causing the first capacitor 48 to be charged with an analog signal Ain from the input terminal 41. Here, the first capacitor 48 has the input terminal on the input terminal 41 side and the output terminal on the output terminal 42 side.

The second switched capacitor circuit 47 is connected in parallel with the feedback capacitor 45. An input terminal of the second switched capacitor circuit 47 is connected to the switch circuit 44, and an output terminal of the second switched capacitor circuit 47 is connected to the output terminal 42 and the output terminal of the amplifier 43. The second switched capacitor circuit 47 comprises a second capacitor 49 and one or more switches. The capacitance of the second capacitor 49 is determined as (1/a−1)*Ci, where a is the value of the feedback coefficient (greater than 0 and less than 1) and Ci is the capacitance of the feedback capacitor 45.

The second switched capacitor circuit 47 repeats charging and discharging the second capacitor 49 corresponding to two phases, φ1 and φ2 (for example, high/low), which repeat within each clock cycle. For example, during the period φ1, the second switched capacitor circuit 47 may short both terminals of the second capacitor 49, causing the second capacitor 49 to discharge. During the period φ2, the second switched capacitor circuit 47 connects one terminal of the second capacitor 49 to one terminal of the feedback capacitor 45 and the other terminal of the second capacitor 49 to the other terminal of the feedback capacitor 45, causing the second capacitor 49 to be charged with the charge discharged by the feedback capacitor 45. The second switched capacitor circuit 47 repeats the operation during the periods φ1 and φ2 to repeatedly charge and discharge the second capacitor 49, thereby realizing a feedback coefficient a of the integrator 40.

In the capacitance (1/a−1)*Ci of the second capacitor 49, the value a may be configured to be variable. That is, the feedback coefficient a of at least one of the multiple integrators 40 included in the analog integration unit 4 may be configured to be variable.

The second capacitor 49 may be a variable capacitor. That is, the integrator 40 may comprise a variable capacitor. This allows the capacitance of the second capacitor 49 to be varied according to each integration operation included in the series of integration operations, thereby enabling the feedback coefficient a of the integrator 40 to be variable. The controller 9 may vary the capacitance of the second capacitor 49 to vary the feedback coefficient a of the integrator 40.

With reference again to FIGS. 1 and 2, at least one of the multiple integrators 70 included in the digital integration unit 7 may comprise the feedback circuit 16 having the gain a set to a value greater than 0 and less than 1. That is, at least one of the multiple integrators 70 included in the digital integration unit 7 may have a feedback coefficient a greater than 0 and less than 1. In the embodiment shown in FIG. 1, all of the multiple integrators 70_1 to 70_m have feedback coefficients a greater than 0 and less than 1. However, the multiple integrators 70 included in the digital integration unit 7 may include an integrator having a feedback coefficient of 1.

The feedback coefficient a of the integrator 70 may be configured to be variable. That is, the feedback coefficient a of at least one of the multiple integrators 70 included in the digital integration unit 7 may be configured to be variable.

When the multiple integrators 70 included in the digital integration unit 7 include two or more integrators 70 each having a feedback coefficient a greater than 0 and less than 1, the values of the feedback coefficients a of the two or more integrators 70 may be different from each other. This allows more detailed design of the resolution and filtering effect in the incremental delta-sigma modulator 1. However, the multiple integrators 70_1 to 70_m shown in FIG. 1 may have feedback coefficients a equal to each other. This reduces the processing load on the controller 9 for controlling the multiple integrators 70 in the incremental delta-sigma modulator 1.

With reference to FIG. 2, the integrator 70, which is a digital integrator, may include a logic circuit for amplifying an input digital signal by the gain a, as the feedback circuit 16. Specifically, the logic circuit as the feedback circuit 16 performs a bit shift processing and an addition processing on the input digital signal to amplify the input digital signal by the gain a. The logic circuit may be configured to change the bit shift calculation processing and the addition processing to vary the gain a in accordance with control by the controller 9. In such a case, the integrator 70 may comprise a logic circuit configured to vary the feedback coefficient a. That is, the controller 9 may control the logic circuit to vary the feedback coefficient a of the integrator 70. In case the feedback coefficient a is greater than 0 and less than 1, the feedback circuit 16 may attenuate the input digital signal. Specifically, the logic circuit acting as the feedback circuit 16 performs bit-shifting and addition processing on the input digital signal to attenuate it by the gain a.

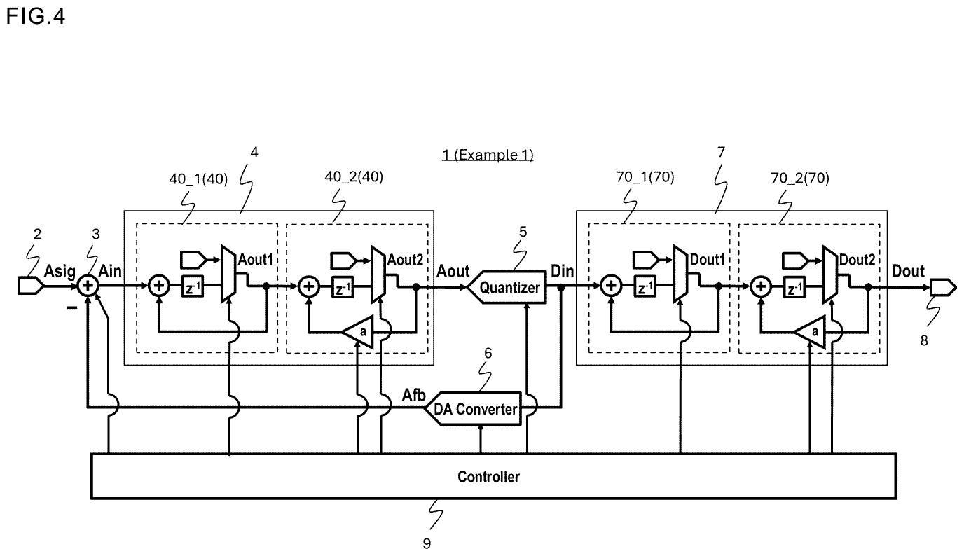

With reference to FIG. 4, the improvement of the resolution and filtering effect realized by the incremental delta-sigma modulator 1 according to the present disclosure will be described. FIG. 4 illustrates a schematic configuration of the incremental delta-sigma modulator 1 in Example 1. In the following description, Example 1 of the incremental delta-sigma modulator 1 includes, as an example, an analog integration unit 4 and a digital integration unit 7 each having two integrators, as shown in FIG. 4. Specifically, the analog integration unit 4 of Example 1 comprises an integrator 40_1 having a feedback coefficient of 1 and an integrator 40_2 having a feedback coefficient a greater than 0 and less than 1. The digital integration unit 7 of Example 1 comprises an integrator 70_1 having a feedback coefficient of 1 and an integrator 70_2 having a feedback coefficient a greater than 0 and less than 1.

In the configuration of Example 1 shown in FIG. 4, the digital signal Dout output from the incremental delta-sigma modulator 1 is derived from the following equations (1) to (10).

Specifically, the analog signal Aout output from the analog integration unit 4 is derived from the following equations (1) to (4).

$${A}_{i n} = {A}_{sig} - {A}_{fb} \qquad ( 1 )$$

$${A}_{out 1} = {z}^{- 1} ( {A}_{i n} + {A}_{out 1} ) \qquad ( 2 )$$

$${A}_{out 1} = \frac{{z}^{- 1}}{1 - {z}^{- 1}} ( {A}_{in} ) \qquad ( 3 )$$

$${A}_{o u t} = {A}_{out 2} = \frac{{z}^{- 1}}{1 - a {z}^{- 1}} ( {A}_{out 1} ) \qquad ( 4 )$$

Here, Asig represents the analog signal received by incremental delta-sigma modulator 1, Ain represents the analog signal input to the analog integration unit 4, Afb represents the feedback analog signal from the DA converter 6, Aout1 represents the analog signal output from the integrator 40_1 of the analog integration unit 4, Aout2 represents the analog signal output from the integrator 40_2 of the analog integration unit 4, Aout represents the analog signal output from the analog integration unit 4, z⁻¹ represents the transfer function of the delay circuit 13, and a represents the feedback coefficient of the integrator 40_2 and the integrator 70_2.

Assuming that the DA converter 6 operates ideally, the digital signal Din output from the quantizer 5 and the feedback analog signal Afb from the DA converter 6 can be the same value, and therefore the following equation (5) is established.

$${A}_{o u t} = ( \frac{{z}^{- 1}}{1 - {z}^{- 1}} ) ( \frac{{z}^{- 1}}{1 - a {z}^{- 1}} ) ( {A}_{sig} - {D}_{i n} ) \qquad ( 5 )$$

Therefore, the digital signal Dout output from the incremental delta-sigma modulator 1 is derived by the following equations (6) to (10).

$${D}_{i n} = {A}_{s i g} - {A}_{out} \frac{( 1 - {z}^{- 1} ) ( 1 - a {z}^{- 1} )}{{z}^{- 2}} \qquad ( 6 )$$

$${D}_{out 1} = \frac{{z}^{- 1}}{1 - {z}^{- 1}} ( {D}_{in} ) \qquad ( 7 )$$

$${D}_{out 2} = \frac{{z}^{- 1}}{1 - {z}^{- 1}} ( {D}_{out 1} ) \qquad ( 8 )$$

$${D}_{o u t 2} = ( \frac{{z}^{- 1}}{1 - {z}^{- 1}} ) ( \frac{{z}^{- 1}}{1 - {az}^{- 1}} ) ( {A}_{sig} - {A}_{o u t} \frac{( 1 - {z}^{- 1} ) ( 1 - a {z}^{- 1} )}{{z}^{- 2}} ) \qquad ( 9 )$$

$${D}_{o u t} = {D}_{out 2} = ( \frac{{z}^{- 1}}{1 - {z}^{1}} ) ( \frac{{z}^{- 1}}{1 - a {z}^{- 1}} ) {A}_{s i g} - {A}_{o u t} \qquad ( 10 )$$

Here, Din represents the digital signal input to the digital integration unit 7, Dout1 represents the digital signal output from the integrator 70_1 of the digital integration unit 7, Dout2 represents the digital signal output from the integrator 70_2 of the digital integration unit 7, and Dout represents the digital signal output from the digital integration unit 7.

As shown in equation (10), the digital signal Dout output from the incremental delta-sigma modulator 1 can be expressed using the input analog signal Asig.

Moreover, since the incremental delta-sigma modulator 1 has a reset operation, the digital signal Dout is expressed by the following equation (11) based on the above equations (7) and (8).

$${D}_{out} ( z ) = ( \frac{{z}^{- 1}}{1 - {z}^{- 1}} ) ( \frac{{z}^{- 1}}{1 - a {z}^{- 1}} ) {D}_{in} ( z ) = {\sum }_{j = 0}^{OSR - 1} {\sum }_{i = 0}^{j} {a}^{( OSR - 1 ) - j} {D}_{i n} [ i ] = {D}_{o u t} [ O S R - 1 ] \qquad ( 11 )$$

Here, OSR represents the oversampling ratio of the incremental delta-sigma modulator 1.

The oversampling ratio (OSR) of the incremental delta-sigma modulator 1 represents the number of times the input signal is sampled during one cycle at the output rate of the incremental delta-sigma modulator 1. The oversampling ratio may be equal to the number of integration operations included in a series of integration operations. The OSR of the incremental delta-sigma modulator 1 is expressed by the following equation (12), where Tclock is the clock cycle of the incremental delta-sigma modulator 1 and Tout is the output rate.

$$O S R = \frac{{T}_{out}}{{T}_{clock}} \qquad ( 12 )$$

As an example, when the oversampling ratio of the incremental delta-sigma modulator 1 is set to 16 (OSR=16), the equation (11) is expressed as the following equations (13) and (14).

$${D}_{o u t} [ 15 ] = {\sum }_{\dot{i} = 0}^{0} {a}^{( 15 - i )} {D}_{i n} [ i ] + {\sum }_{i = 0}^{1} {a}^{( 14 - i )} {D}_{i n} [ i ] + … + {\sum }_{i = 0}^{15} {a}^{i} {D}_{i n} [ i ] \qquad ( 13 )$$

$${D}_{o u t} [ 15 ] = {\sum }_{\dot{i} = 0}^{15} {a}^{( 15 - i )} {D}_{i n} [ 0 ] + {\sum }_{i = 0}^{14} {a}^{( 14 - i )} {D}_{i n} [ 1 ] + … + {\sum }_{i = 0}^{0} {a}^{0 - i} {D}_{i n} [ 15 ] \qquad ( 14 )$$

Here, Din[i] and Dout[i] represent the digital signal input to the digital integration unit 7 and the digital signal output from the digital integration unit 7 in the i-th sampling (0≤i≤15), respectively.

From equation (14), the filter coefficients of Din[0] to Din[15] are respectively expressed by expression (15).

$${\sum }_{i = 0}^{15} {a}^{( 15 - i )} , {\sum }_{i = 0}^{14} {a}^{( 14 - i )} , … {\sum }_{i = 0}^{0} {a}^{0 - i} \qquad ( 15 )$$

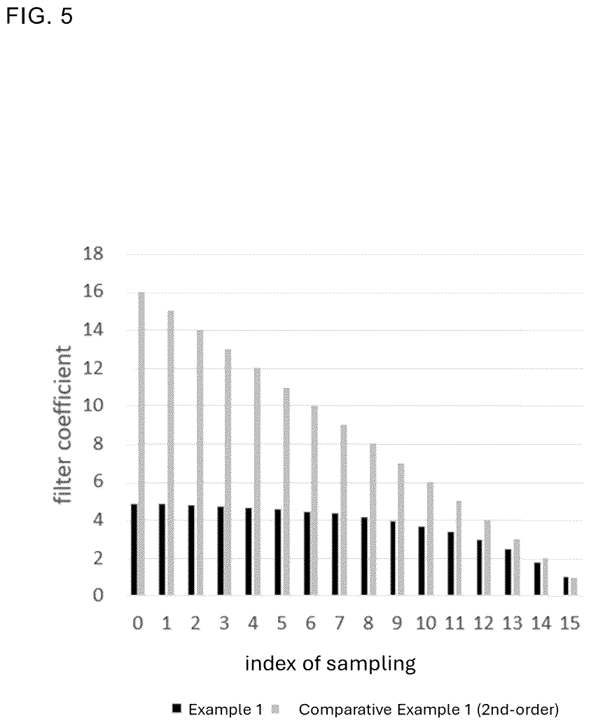

With reference to FIG. 5, the characteristics of the filter coefficient of the incremental delta-sigma modulator 1 will be described. FIG. 5 is a graph illustrating the filter coefficients of the incremental delta-sigma modulators in Example 1 and Comparative Example 1. FIG. 5 shows, as Example 1, the filter coefficients of the incremental delta-sigma modulator 1 shown in FIG. 4 when the feedback coefficient a and the oversampling ratio OSR of the integrator 40_2 and the integrator 70_2 are expressed by a=¾ and OSR=16, respectively.

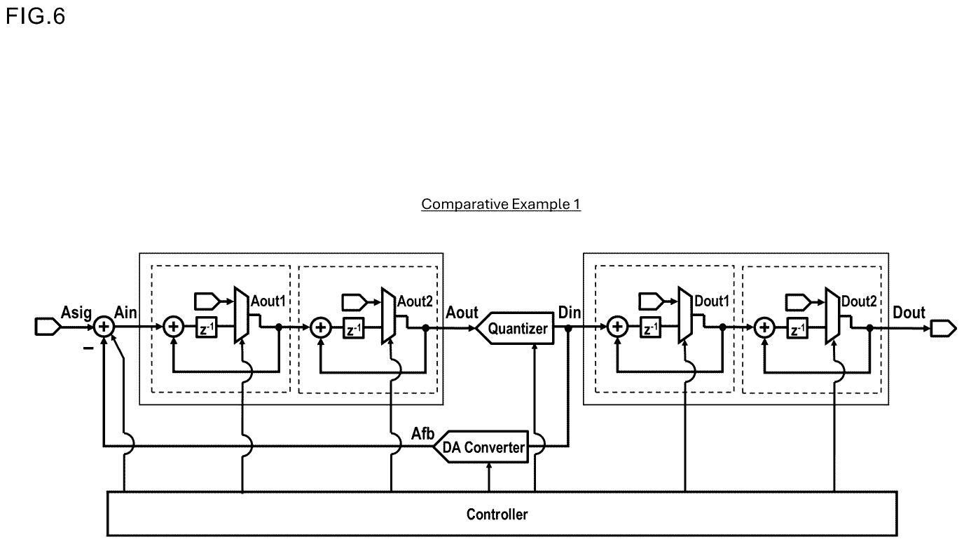

FIG. 5 also shows, as Comparative Example 1, the filter coefficients of a second-order incremental delta-sigma modulator, which comprises an analog integration unit and a digital integration unit, each having two integrators in series. In Comparative Example 1, each of the integrators has a feedback coefficient of 1. The schematic configuration of the incremental delta-sigma modulator in Comparative Example 1 is shown in FIG. 6.

With reference to FIG. 5, in Comparative Example 1, the filter coefficient at the 0th sampling is 16 times greater than the filter coefficient at the 15th sampling. On the other hand, in Example 1, the filter coefficient at the 0th sampling is about 5 times greater than the filter coefficient at the 15th sampling. The slope of the filter coefficients from the 0th to the 15th sampling is gentler in Example 1 compared to Comparative Example 1 in FIG. 5. Therefore, Example 1 can suppress bias in the weighting between samplings compared to Comparative Example 1.

As described above, the incremental delta-sigma modulator 1 according to the present disclosure can suppress bias in the weighting between samplings compared to the conventional technology when the oversampling ratio OSR is increased to, for example, 16, 32, or 64 to increase the resolution, since at least one of the integrators 70 included in the digital integration unit 7 has a feedback coefficient a greater than 0 and less than 1. Moreover, the filter coefficients of Example 1 shown in FIG. 5 can be varied by adjusting the feedback coefficient a, as shown in equation (15). FIG. 5 shows that Example 1 has a smaller value of the filter coefficient at each sampling than Comparative Example 1. The filter coefficients at each sampling of Example 1 can be made closer to those of Comparative Example 1 by varying the feedback coefficient a closer to 1. On the other hand, the filter coefficients at each sampling of Example 1 can be made smaller by varying the feedback coefficient a closer to 0.

Therefore, the incremental delta-sigma modulator 1 according to the present disclosure can achieve both high resolution and high filtering effect. Moreover, the incremental delta-sigma modulator 1 according to the present disclosure can achieve the required resolution and the required filtering effect by adjusting the feedback coefficient a and the oversampling ratio OSR.

Next, the filtering effect of the incremental delta-sigma modulator 1 will be described. Since the incremental delta-sigma modulator 1 has a reset operation, the digital signal Dout is expressed in the form of a finite impulse Response (FIR) filter as shown in the following equation (16).

$$\begin{matrix}{D}_{o u t} [ 15 ] = {\sum }_{i = 0}^{15} {a}^{( 15 - i )} {D}_{i n} [ 0 ] + {\sum }_{i = 0}^{14} {a}^{( 14 - i )} {D}_{in} [ 1 ] + … + {\sum }_{i = 0}^{0} {a}^{0 - i} {D}_{in} [ 15 ] \\ = ( {\sum }_{i = 0}^{0} {a}^{0 - i} {z}^{- 0} + … + {\sum }_{i = 0}^{15} {a}^{( 15 - i )} {z}^{- 15} ) {D}_{i n} ( z )\end{matrix} \qquad ( 16 )$$

Therefore, the transfer function Hscaled(z) of the integration filter in the integration operation of the incremental delta-sigma modulator 1 is expressed by the following equation (17).

$${H}_{scaled} ( z ) = ( {\sum }_{i - 0}^{0} {a}^{0 - i} {z}^{- 0} + … + {\sum }_{i = 0}^{1 S} {a}^{( 15 - i )} {z}^{- 15} ) \qquad ( 17 )$$

Here, z represents a complex variable, z^{-t} represents the delay at the t-th sampling. In equation (17), as the value (absolute value) of the exponent t becomes smaller, the z^{-t} represents more new data.

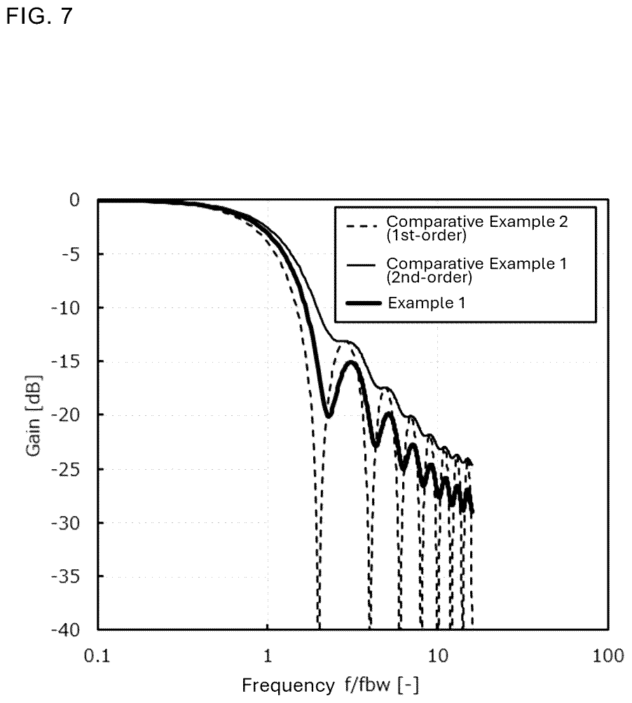

By substituting z=e^{jω} into equation (17), the data shown by the bold line in FIG. 7 is obtained. FIG. 7 is a graph illustrating the transfer functions of the incremental delta-sigma modulators in Example 1 and Comparative Examples 1 and 2. In FIG. 7, the horizontal axis indicates normalized frequency with the bandwidth frequency of the incremental delta-sigma modulators set to 1, and the vertical axis indicates gain applied to the input of the frequency on the horizontal axis.

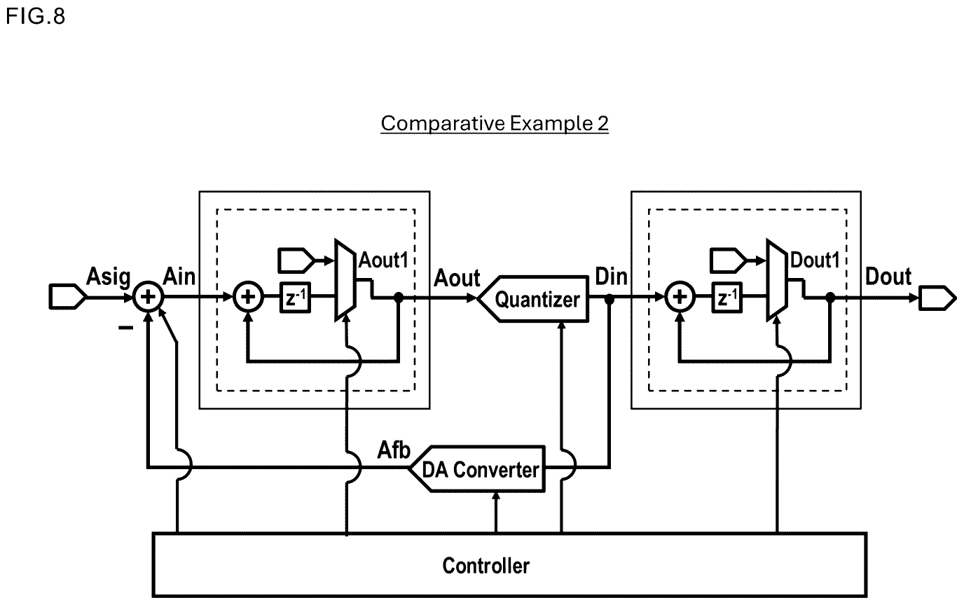

FIG. 7 shows, in addition to the above-mentioned Example 1 and Comparative Example 1, the filter coefficients of a first-order incremental delta-sigma modulator of Comparative Example 2, which comprises an analog integration unit and a digital integration unit, each having one integrator with a feedback coefficient of 1. The schematic configuration of the incremental delta-sigma modulator in Comparative Example 2 is shown in FIG. 8.

As FIG. 7 shows that the slope of the line of Comparative Example 1 is gentler than that of Comparative Example 2, Comparative Example 1 cannot efficiently reduce noises in various frequency bands compared to Comparative Example 2. This is due to bias in the weighting between samplings, as shown in FIG. 5. Accordingly, increasing the order of the incremental delta-sigma modulator to improve resolution instead causes significant degradation in its filtering effect in the conventional technology.

FIG. 7 also shows that Example 1 is closer in shape to Comparative Example 2 than Comparative Example 1. This means that although the order of Example 1 is higher than that of Comparative Example 2, as in Comparative Example 1, Example 1 has an improved noise reduction filtering effect in various frequency bands than Comparative Example 1. This is because, as shown in FIG. 5, varying the weights of each sampling to make them more uniform improves the averaging effect. Moreover, as shown in equation (17), the noise reduction filtering effect of Example 1 can be modified by adjusting the feedback coefficient a and the oversampling ratio OSR.

Therefore, the incremental delta-sigma modulator 1 according to the present disclosure can improve the noise reduction filtering effect without compromising resolution. Moreover, the incremental delta-sigma modulator 1 according to the present disclosure can achieve a required noise reduction filtering effect by adjusting the feedback coefficient a and the oversampling ratio OSR.

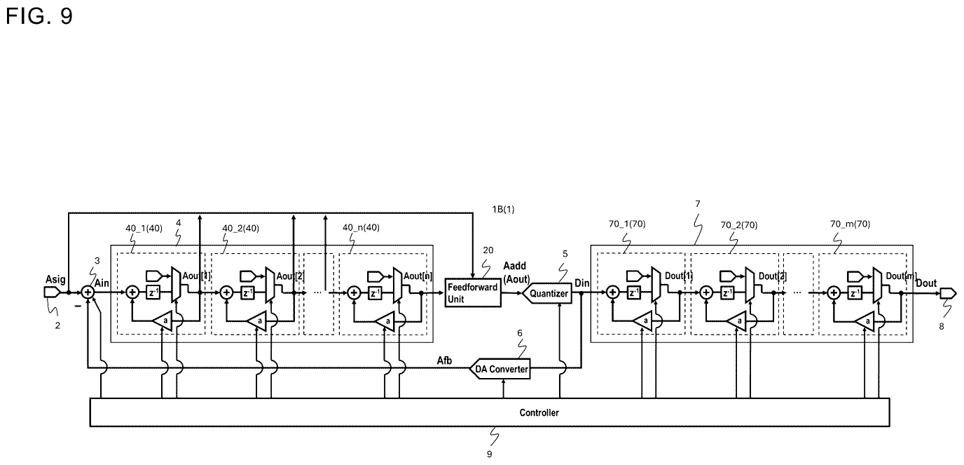

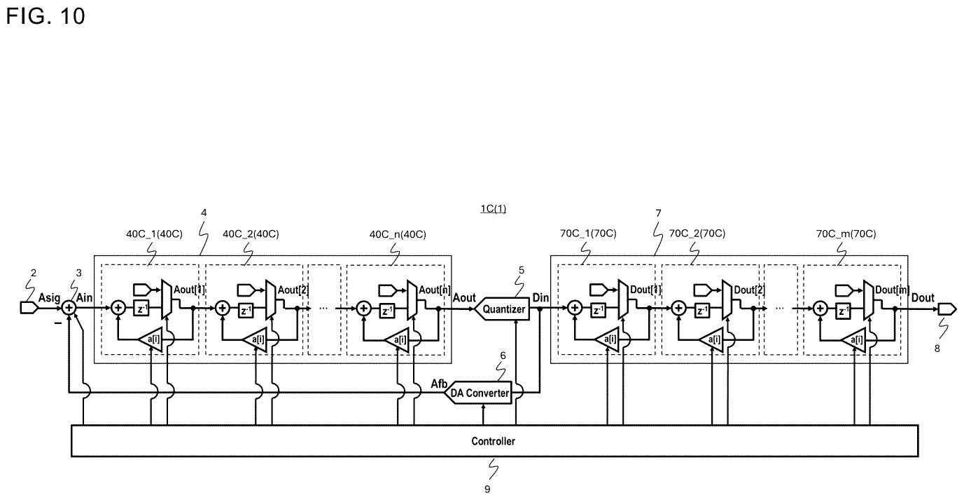

With reference to FIG. 9 and FIG. 10, modified examples of the incremental delta-sigma modulator 1 described above will be explained. FIG. 9 illustrates a schematic configuration of the incremental delta-sigma modulator 1B, which is the first modified example of the incremental delta-sigma modulator 1. FIG. 10 illustrates a schematic configuration of the incremental delta-sigma modulator 1C, which is the second modified example of the incremental delta-sigma modulator 1. In the following description, each modified example of the incremental delta-sigma modulator 1 will be described, focusing on the differences from the incremental delta-sigma modulator 1A shown in FIG. 1. In each modified example, the description of the parts having the same or corresponding configuration as the incremental delta-sigma modulator 1A will be omitted or simplified as appropriate. In each drawing of the modified example, the same reference characters designate the same or corresponding parts as the incremental delta-sigma modulator 1A.

With reference to FIG. 9, a configuration of the incremental delta-sigma modulator 1B, which is the first modified example of the incremental delta-sigma modulator 1, will be explained. Unlike the incremental delta-sigma modulator 1A, the incremental delta-sigma modulator 1B comprises a feedforward unit 20.

The feedforward unit 20 is an adder that adds analog signals Aout[1] to Aout[n] respectively output from the multiple integrators 40_1 to 40_n included in the analog integration unit 4 and the analog signal Asig received by the input terminal 2 to generate an added signal Aadd, and outputs the added signal Aadd, as the analog signal Aout, to the quantizer 5.

The feedforward unit 20 is connected to the input terminal 2, the multiple integrators 40_1 to 40_n included in the analog integration unit 4, and the quantizer 5. The feedforward unit 20 receives the analog signal Asig from the input terminal 2 and the analog signals Aout[1] to Aout[n] respectively from the multiple integrators 40_1 to 40_n included in the analog integration unit 4. The feedforward unit 20 adds the analog signal Asig and the analog signals Aout[1] to Aout[n] to generate an analog signal Aadd. For example, as shown in the following equation (18), the analog signal Asig and the analog signals Aout[1] to Aout[n] may be weighted and then added.

$${A}_{add} = {a}_{0} * {A}_{s i g} + {a}_{1} * {A}_{o u t [ 1 ]} + {a}_{2} * {A}_{o u t [ 2 ]} + … + {a}_{n} * {A}_{o u t [ n ]} \qquad ( 18 )$$

The feedforward unit 20 outputs the added analog signal Aadd, as the analog signal Aout, to the quantizer 5. As a result, the incremental delta-sigma modulator 1 achieves improved stability in the analog domain.

With reference to FIG. 10, the configuration of an incremental delta-sigma modulator 1C, which is the second modified example of the incremental delta-sigma modulator 1, will be explained. Unlike the incremental delta-sigma modulator 1A, the incremental delta-sigma modulator 1C comprises the multiple integrators 40C in the analog integration unit 4 where the feedback coefficients a[i] of the multiple integrators 40C are configured to be variable within a range greater than 0 and equal to or less than 1. Furthermore, the incremental delta-sigma modulator 1C comprises the multiple integrators 70C in the digital integration unit 7 where the feedback coefficients a[i] of the multiple integrators 70C are configured to be variable within a range greater than 0 and equal to or less than 1.

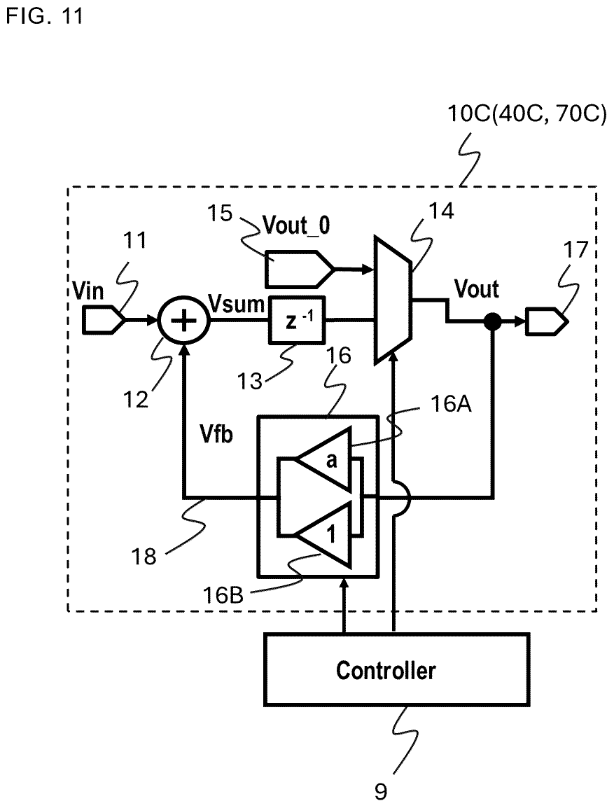

With reference to FIG. 11, the integrator 10C (40C, 70C) included in the incremental delta-sigma modulator 1C will be explained, focusing on the differences from the integrator 10 (40, 70) shown in FIG. 2. As shown in FIG. 11, the integrator 10C (40C, 70C) included in the incremental delta-sigma modulator 1C may comprise: a first feedback module 16A having a feedback coefficient a greater than 0 and less than 1; and a second feedback module 16B having a feedback coefficient of 1, for example in the feedback circuit 16. Each of the first feedback module 16A and the second feedback module 16B may comprise one or more electronic components. The first feedback module 16A and the second feedback module 16B may be configured to be switchable, for example, by a control signal from the controller 9. This allows a single integrator 10C (40C, 70C) to operate as an integrator having a feedback coefficient a greater than 0 and less than 1, or as an integrator having a feedback coefficient of 1, depending on the required resolution and the required filtering effect.

Moreover, in the incremental delta-sigma modulator 1C, the feedback coefficients a[i] of the multiple integrators 40 included in the analog integration unit 4 and the feedback coefficients a[i] of the multiple integrators 70 included in the digital integration unit 7 may be configured to be dynamically variable within a range greater than 0 and less than or equal to 1 during a series of integration operations. More specifically, the feedback coefficients a[i] of the multiple integrators 40 included in the analog integration unit 4 and the feedback coefficients a[i] of the multiple integrators 70 included in the digital integration unit 7 may be configured to be varied according to each integration operation included in the series of integration operations. In such a case, the feedback coefficient a[i] may refer to the feedback coefficient of the i-th integration operation in the series of integration operations.

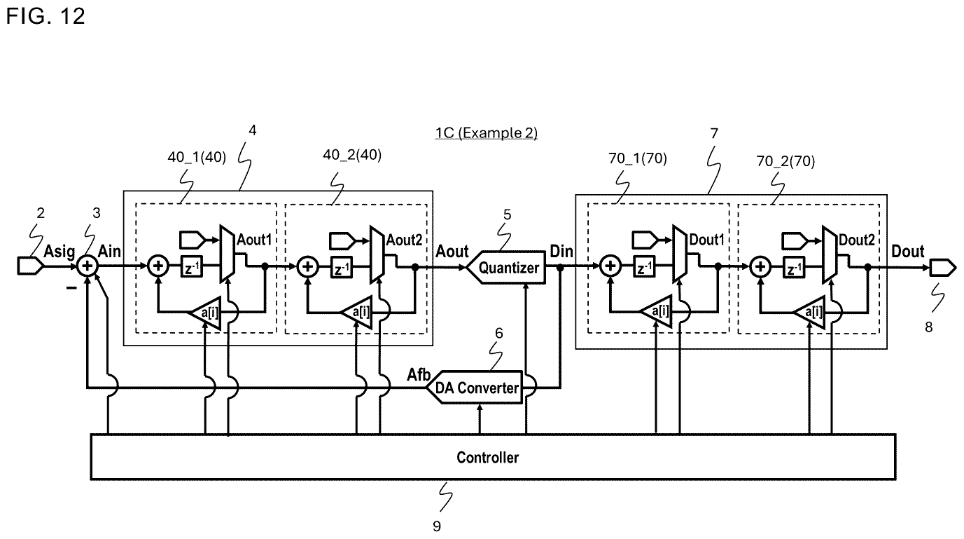

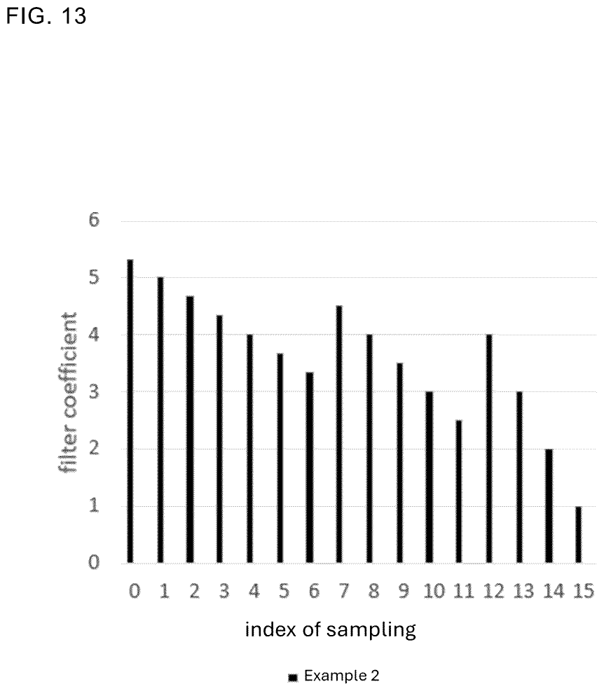

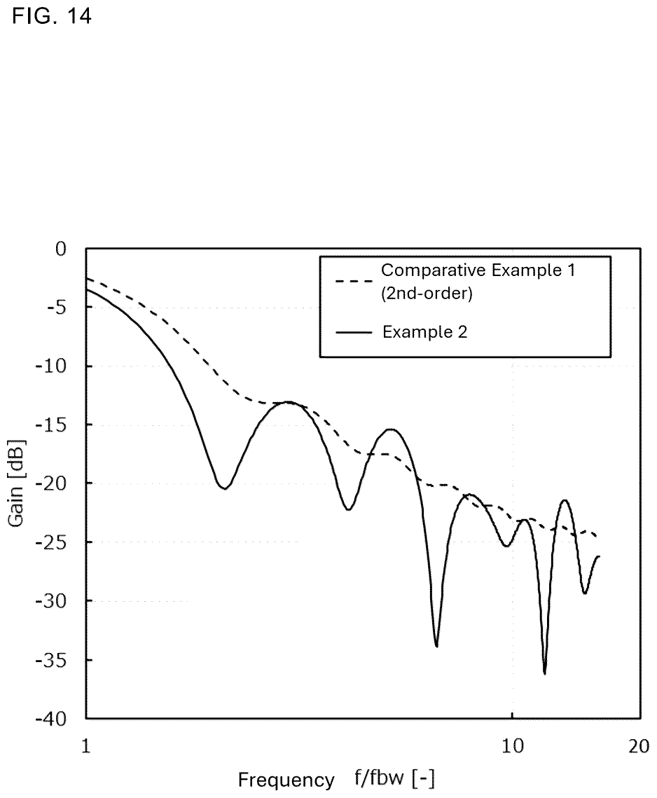

With reference to FIG. 12, FIG. 13, and FIG. 14, the improved resolution and filter effect achieved by the incremental delta-sigma modulator 1C will be described. FIG. 12 illustrates a schematic configuration of the incremental delta-sigma modulator 1C in Example 2. FIG. 13 is a graph illustrating the filter coefficients of the incremental delta-sigma modulators in Example 2. FIG. 14 is a graph illustrating the transfer functions of the incremental delta-sigma modulators in Example 2 and Comparative Example 1. In FIG. 14, the horizontal axis indicates normalized frequency with the bandwidth frequency of the incremental delta-sigma modulator 1C set to 1, and the vertical axis indicates gain applied to the input of the frequency on the horizontal axis.

In the following description, as an example, the incremental delta-sigma modulator 1C in Example 2 includes an analog integration unit 4 and a digital integration unit 7 each having two integrators as shown in FIG. 12. Specifically, the analog integration unit 4 includes integrators 40_1 and 40_2, each having the feedback coefficient a[i] variable in the range from greater than 0 to less than or equal to 1. The digital integration unit 7 includes integrators 70_1 and 70_2, each having the feedback coefficient a[i] variable in the range from greater than 0 to less than or equal to 1

The feedback coefficients a[i] of the multiple integrators 40 included in the analog integration unit 4 and the feedback coefficients a[i] of the multiple integrators 70 included in the digital integration unit 7 may be set to a value greater than 0 and less than 1 in one or more predetermined integration operations included in the series of integration operations, and may be set to 1 in integration operations other than the one or more predetermined integration operations. FIG. 13 shows, as Example 2, the filter coefficients of the incremental delta-sigma modulator 1C shown in FIG. 12 when the oversampling ratio OSR is set to 16 and the feedback coefficients a[i] of the integrators 40_1, 40_2 and the integrators 70_1, 70_2 are dynamically varied according to the following equation (19).

$$a [ i ] = 1 ( if i \neq 7 or 12 ) , \qquad ( 19 )$$

$$a [ i ] = \frac{1}{1.5} ( if i = 7 ) ,$$

$$a [ i ] = \frac{1}{2} ( if i = 12 ) ,$$

With reference to FIG. 13, dynamically varying the feedback coefficients a[i] of integrators 40_1, 40_2 and the integrators 70_1, 70_2 allows Example 2 to have larger filter coefficient values at specific samplings compared to Example 1 shown in FIG. 5. With this configuration, the weights of each sampling become more uniform, and as a result, as shown in FIG. 14, Example 2 can be designed to have an improved noise reduction filtering effect in specific frequency bands. In Example 2, the feedback coefficients a[i] of the integrators 40_1, 40_2 and the integrators 70_1, 70_2 are varied uniformly. However, the feedback coefficients a[i] of the integrators 40_1, 40_2 and the integrators 70_1, 70_2 included in the incremental delta-sigma modulator 1C may be varied individually.

Therefore, the incremental delta-sigma modulator 1C according to the present disclosure can achieve both high resolution and high filtering effect. Moreover, the incremental delta-sigma modulator 1C according to the present disclosure can achieve the required resolution and the required filtering effect by dynamically varying the feedback coefficient a in a series of integration operations.

As described above with reference to the accompanying drawings, an incremental delta-sigma modulator 1 according to the present disclosure comprises: an analog integration unit 4 including multiple integrators 40 connected in series and configured to integrate an analog signal, each of the multiple integrators 40 having a first-order or higher-order feedback coefficient; a quantizer 5 configured to quantize a signal output from the analog integration unit 4; a DA converter 6 configured to convert a digital signal output from the quantizer 5 into a feedback analog signal and output the feedback analog signal to the analog integration unit 4; a digital integration unit 7 including multiple integrators 70 connected in series and configured to integrate the digital signal from the quantizer 6, each of the multiple integrators 70 having a first-order or higher-order feedback coefficient; and a controller 9 configured to reset each of the multiple integrators 40 included in the analog integration unit 4 and the multiple integrators 70 included in the digital integration unit 7 for each series of integration operations. At least one of the multiple integrators 70 included in the digital integration unit 7 has a feedback coefficient a greater than 0 and less than 1.

Such incremental delta-sigma modulator 1 can achieve both high resolution and high filtering effect. Moreover, the incremental delta-sigma modulator 1 according to the present disclosure can achieve the required resolution and the required filtering effect by adjusting the feedback coefficient a. Therefore, the present disclosure can provide an incremental delta-sigma modulator 1 with improved utility.

While the present disclosure has been described with reference to the drawings and examples, it should be noted that various modifications and revisions may be implemented by those skilled in the art based on the present disclosure. Accordingly, such modifications and revisions are included within the scope of the present disclosure. For example, configurations, functions, or the like included in each embodiment can be rearranged without logical inconsistency. In addition, configurations or functions included in each embodiment can be used in combination with another embodiment, and multiple configurations or functions can be combined into one, divided, or partially omitted.

### REFERENCE SIGNS IN FIGURES

1(1A, 1B, 1C): Incremental delta-sigma modulator,
2: Input terminal,
3: Adder-subtractor,
4: Analog integration unit,
40(40_1 to 40_n, 40C, 40C_1 to 40C_n): Integrator (Analog integrator),
41: Input terminal,
42: Output terminal,
43: Amplifier,
44: Switch circuit,
45: Feedback capacitor,
46: First switched capacitor circuit,
47: Second switched capacitor circuit,
48: First capacitor,
49: Second capacitor,
5: Quantizer,
6: DA converter (Digital-to-Analog converter),
7: Digital integration unit,
70(70_1 to 70_m, 70C, 70C_1 to 70C_n): Integrator (Digital integrator),
8: Output terminal,
9: Controller,
10(10C): Integrator,
11: Input terminal,
12: Adder,
13: Delay circuit,
14: Switch circuit,
15: Reset circuit,
16: Feedback circuit,
16A: First feedback module,
16B: Second feedback module,
17: Output terminal,
18: Feedback path,
20: Feedforward unit,
Asig, Ain, Aout, Afb, Aout[1], Aout[2], Aout[n], Aadd: Analog signal,
Din, Dout, Dout[1], Dout[2], Dout[m]: Digital signal, and
Vin, Vout, Vfb, Vsum, Vout_0: Signal.

1. An incremental delta-sigma modulator comprising:
an analog integration unit including multiple integrators connected in series and configured to integrate an analog signal, each of the multiple integrators having a first-order or higher-order feedback coefficient;
a quantizer configured to quantize a signal output from the analog integration unit;
a DA (Digital-to-Analog) converter configured to convert a digital signal output from the quantizer into a feedback analog signal and output the feedback analog signal to the analog integration unit;
a digital integration unit including multiple integrators connected in series and configured to integrate the digital signal from the quantizer, each of the multiple integrators having a first-order or higher-order feedback coefficient; and
a controller configured to reset each of the multiple integrators included in the analog integration unit and the multiple integrators included in the digital integration unit for each series of integration operations, wherein
at least one of the multiple integrators included in the digital integration unit has a feedback coefficient greater than 0 and less than 1.

2. The incremental delta-sigma modulator according to claim 1, wherein
the feedback coefficient of the at least one of the multiple integrators included in the digital integration unit is configured to be variable.

3. The incremental delta-sigma modulator according to claim 2, wherein
the at least one of the multiple integrators included in the digital integration unit comprises a logic circuit configured to vary the feedback coefficient.

4. The incremental delta-sigma modulator according to claim 1, wherein
the multiple integrators included in the digital integration unit include two or more integrators, each having the feedback coefficient greater than 0 and less than 1, and
values of the feedback coefficients of the two or more integrators are different from each other.

5. The incremental delta-sigma modulator according to claim 1, wherein
the at least one of the multiple integrators included in the digital integration unit comprises: a first feedback module having the feedback coefficient greater than 0 and less than 1; and a second feedback module having a feedback coefficient of 1, and
the first feedback module and the second feedback module are configured to be switchable.

6. The incremental delta-sigma modulator according to claim 1, wherein
at least one of the multiple integrators included in the analog integration unit has the feedback coefficient greater than 0 and less than 1.

7. The incremental delta-sigma modulator according to claim 6, wherein
the feedback coefficient of the at least one of the multiple integrators included in the analog integration unit is configured to be variable.

8. The incremental delta-sigma modulator according to claim 7, wherein
the at least one of the multiple integrators included in the analog integration unit comprises a variable capacitor, and
the feedback coefficient of the at least one of the multiple integrators included in the analog integration unit is configured to be varied according to each integration operation included in the series of integration operations.

9. The incremental delta-sigma modulator according to claim 6, wherein
the multiple integrators included in the analog integration unit include two or more integrators, each having the feedback coefficient greater than 0 and less than 1, and
values of the feedback coefficients of the two or more integrators are different from each other.

10. The incremental delta-sigma modulator according to claim 6, wherein
the at least one of the multiple integrators included in the analog integration unit comprises: a first feedback module having the feedback coefficient greater than 0 and less than 1; and a second feedback module having a feedback coefficient of 1, and
the first feedback module and the second feedback module are configured to be switchable.

11. The incremental delta-sigma modulator according to claim 1, wherein
a number of the multiple integrators included in the digital integration unit is greater than a number of the multiple integrators included in the analog integration unit.

12. The incremental delta-sigma modulator according to claim 1, further comprising:
an input terminal configured to receive an analog signal; and
an adder-subtractor configured to subtract the feedback analog signal from the DA converter from the analog signal received at the input terminal to generate a subtracted analog signal and output the subtracted analog signal to the analog integration unit.

13. The incremental delta-sigma modulator according to claim 12, further comprising an adder coupled between the analog integration unit and the quantizer, wherein
the adder is configured to:
add signals output from the multiple integrators included in the analog integration unit and the analog signal received by the input terminal to generate an added signal and;
output the added signal to the quantizer.
